(19) United States
(12) Patent Application Publication
(10) Pub. No.: US 2015/0053462 A1
(43) Pub. Date: Feb. 26, 2015

(54) WIRING BOARD STRUCTURE

(71) Applicant: Unimicron Technology Corp., Taoyuan (TW)

(72) Inventors: Ming-Hao Wu, Taoyuan County (TW); Wei-Ming Cheng, Kaohsiung City (TW); Hung-Lin Chang, Taoyuan County (TW)

(73) Assignee: Unimicron Technology Corp., Taoyuan (TW)

(21) Appl. No.: 14/062,912

(22) Filed: Oct. 25, 2013

(30) Foreign Application Priority Data
Aug. 22, 2013 (TW) 102130006

(51) Int. Cl. H05K 1/02

(52) U.S. Cl. CPC H05K 1/0206; H05K 2201/06
USPC 174/252

(57) ABSTRACT

A wiring board structure adapted to carry a heat generating component is provided. The wiring board structure includes a core layer, an active cooler, a dielectric layer and a plurality of conductive vias. The core layer has a cavity penetrating through the core layer. The active cooler includes a cold surface and a hot surface. The active cooler is disposed in the cavity. The dielectric layer covers the core layer and fills a gap between the active cooler and the cavity. The heat-generating component is disposed on an outer surface of the dielectric layer. The conductive vias are disposed in the dielectric layer and connecting the cold surface and the outer surface to connect the heat-generating component and the active cooler. A wiring board structure having an active cooling via is also provided.

### CROSS-REFERENCE TO RELATED APPLICATION

This application claims the priority benefit of Taiwan application serial no. 102130006, filed on Aug. 22, 2013. The entirety of the above-mentioned patent application is hereby incorporated by reference herein and made a part of this specification.

### BACKGROUND OF THE INVENTION

1. Field of the Invention

The invention relates to a wiring board structure, and more particularly to a wiring board structure having more preferable heat dissipation efficiency.

2. Description of Related Art

Advancement of technology leads to continuous development of portable electronic devices towards compactness and capabilities for performing multiple functions. For instance, tablet computers or smart phones with compact-sized and low-profiled appearances are suitable for users to carry and operate. Accordingly, the more powerful electronic devices require chips of higher speed. However, as the chips with higher speed generate more heat, and the electronic devices are miniaturized, heat dissipation modules have become an indispensable component in the electronic devices.

In conventional electronic products such as desktop computers or notebook computers, a common heat dissipation design for the desktop computers or notebook computers achieves effectiveness of heat dissipation by installing components including fans and heat dissipation fins around heat source. However, since the portable electronic devices such as the tablet computer and the smart phones include a relatively smaller internal space, spaces for heat dissipation in said portable electronic devices are restricted and compressed. Designs toward extremely compressed space results in difficulties for heat dissipation. Further, problems regarding heat dissipation encountered by the portable electronic devices are also related to complexity of the devices. Circuit design for smart electronic devices with multiple functions is relatively more complex, which also influences in design for high efficiency heat dissipation. Accordingly, heat of the portable electronic devices is concentrated at where the chips are located without being radiated to the outside. As a result, this not only results in discomfort for the users in use, but also possibly leads to damages on the chips.

### SUMMARY OF THE INVENTION

The invention is directed to a wiring board structure having an active cooling function which is capable of improving the heat dissipation efficiency of the wiring board structure.

The invention provides a wiring board structure adapted to carry a heat-generating component. The wiring board structure includes a core layer, an active cooler, a first dielectric layer and a plurality of first conductive vias. The core layer has a cavity penetrating through the core layer. The active cooler includes a cold surface and a hot surface. The active cooler is disposed in the cavity. The first dielectric layer covers a surface of the core layer and the cold surface and fills a gap between the cavity and the active cooler. The first dielectric layer includes a first outer surface not contacting the core layer and the active cooler for disposing the heat-generating component. The first conductive vias are disposed in the first dielectric layer and connecting the cold surface and the first outer surface to connect the heat-generating component and the active cooler.

A wiring board structure according to another embodiment of the invention is adapted to carry a heat-generating component, and the wiring board structure includes a first dielectric layer, a plurality of first conductive vias and an active cooling material. The first dielectric layer includes a first surface and a second surface opposite to the first surface. The first conductive vias are disposed in the first dielectric layer and respectively connecting through the first surface and the second surface. The active cooling material is applied to fill each of the first conductive vias so that each of the first conductive vias has a hot surface and a cold surface respectively corresponding to the second surface and the first surface of the first dielectric layer. The first surface and the cold surface are respectively for disposing and connecting with the heat-generating component.

Based on above, in the invention, the active cooler is embedded in the wiring board structure, or the active cooling material is applied to fill the conductive vias of the wiring board structure. Accordingly, with a characteristic in which a cold surface and a hot surface are respectively formed on two opposite surfaces of the active cooler or the conductive vias filled with the active cooling material when an electric current is conducted thereto for providing an active heat conduction, the cold surface can be connected to the heat-generating component through the first conductive vias to absorb heat from the heat-generating component through the cold surface, and radiate the heat through the hot surface. As a result, the wiring board structure of the invention can rapidly dissipate the heat generated by the heat-generating component during operation to avoid unnecessary heat accumulation, so as to improve a heat dissipation efficiency of the wiring board structure.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a wiring board structure according to an embodiment of the invention.

FIGS. 2A to 2H are schematic cross-sectional views illustrating a fabricating process of a wiring board structure according to an embodiment of the invention.

FIGS. 3A to 3C are schematic cross-sectional views illustrating a fabricating process of a wiring board structure according to another embodiment of the invention.

FIG. 4 is a schematic view of a wiring board structure according to yet another embodiment of the invention.

FIGS. 5A to 5D are schematic cross-sectional views of a fabricating process of the wiring board structure depicted in FIG. 4.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

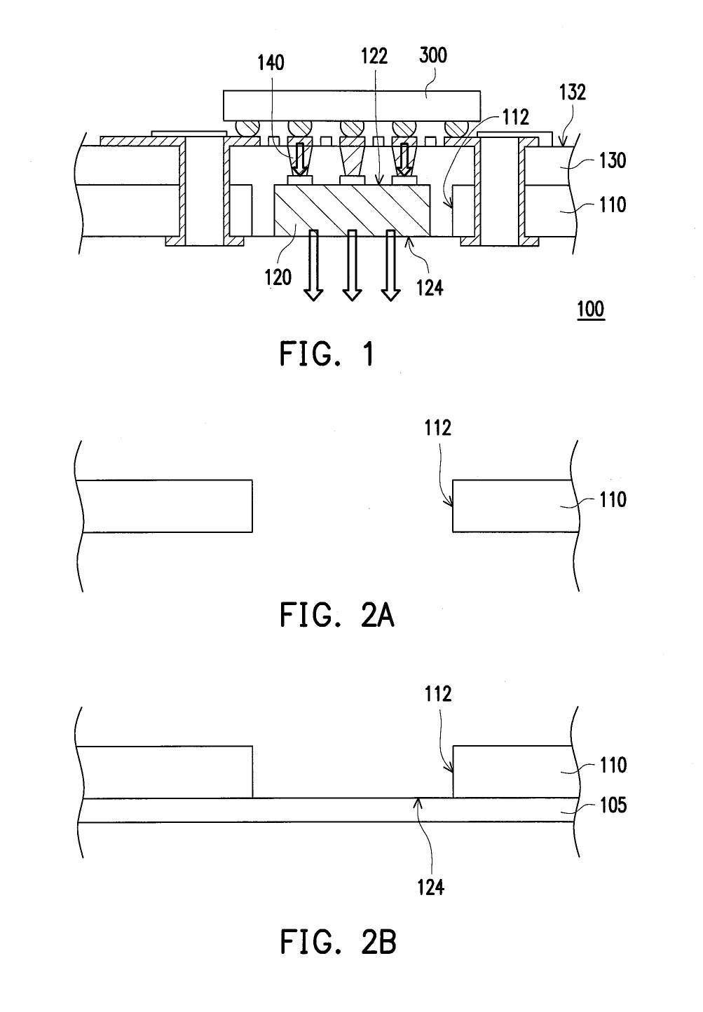

FIG. 1 is a schematic view of a wiring board structure according to an embodiment of the invention. Referring to FIG. 1, a wiring board structure 100 is adapted to carry a heat-generating component 300. The wiring board structure 100 includes a core layer 110, an active cooler 120, a first dielectric layer 130 and a plurality of first conductive vias 140. The core layer 110 has a cavity 112 penetrating the core layer 110. The active cooler 120 is disposed in the cavity 112, and includes a cold surface 122 and a hot surface 124, in which heat of the heat-generating component 300 can absorbed through the cold surface 122, and the absorbed heat can be radiated through the hot surface 124. In the present embodiment, the active cooler 120 is a thermal-electric cooler (TEC) which includes a N-type semiconductor material and a P-type semiconductor material, and said materials can be tellurium (Te) and bismuth (Bi) or any other suitable material. The first dielectric layer 130 covers the core layer 110 and fills a gap between the cavity 112 and the active cooler 120. As an embodiment of the wiring board structure 100, the heat-generating component 300 can be disposed on an outer surface 132 of the dielectric layer 130. The first conductive vias 140 are disposed in the first dielectric layer 130 and connecting the cold surface 122 and the first outer surface 132 to connect the heat-generating component 300 and the active cooler 120.

When an electric current is conducted to the active cooler 120, the cold surface 122 is formed on one end of the active cooler 120 while the hot surface 124 is formed on another end of the active cooler 120. In the present embodiment, the cold surface 122 of the active cooler 120 is connected to the heat generating component 300 through the first conductive vias 140 to absorb heat generated by the heat-generating component 300, and radiate the heat through the hot surface 124. Therein, a thermal conduction path of the wiring board structure 100 can refer to hollow arrows depicted in FIG. 1. As a result, the heat generated by the heat-generating component during operation can be rapidly dissipated to avoid unnecessary heat accumulation, so as to improve a heat dissipation efficiency of the wiring board structure.

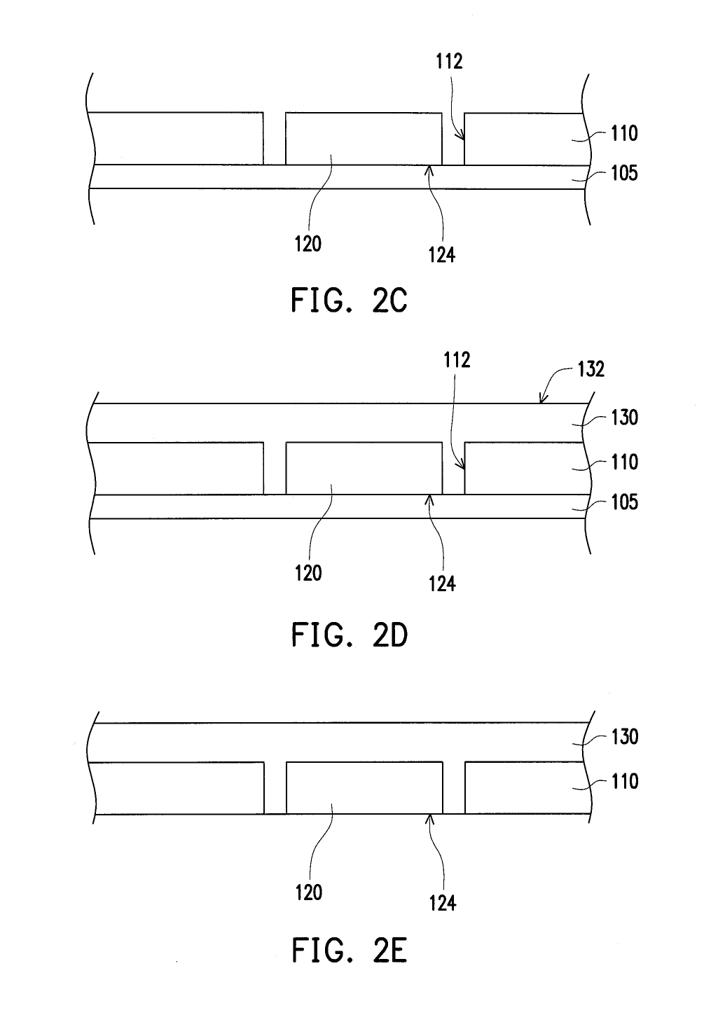

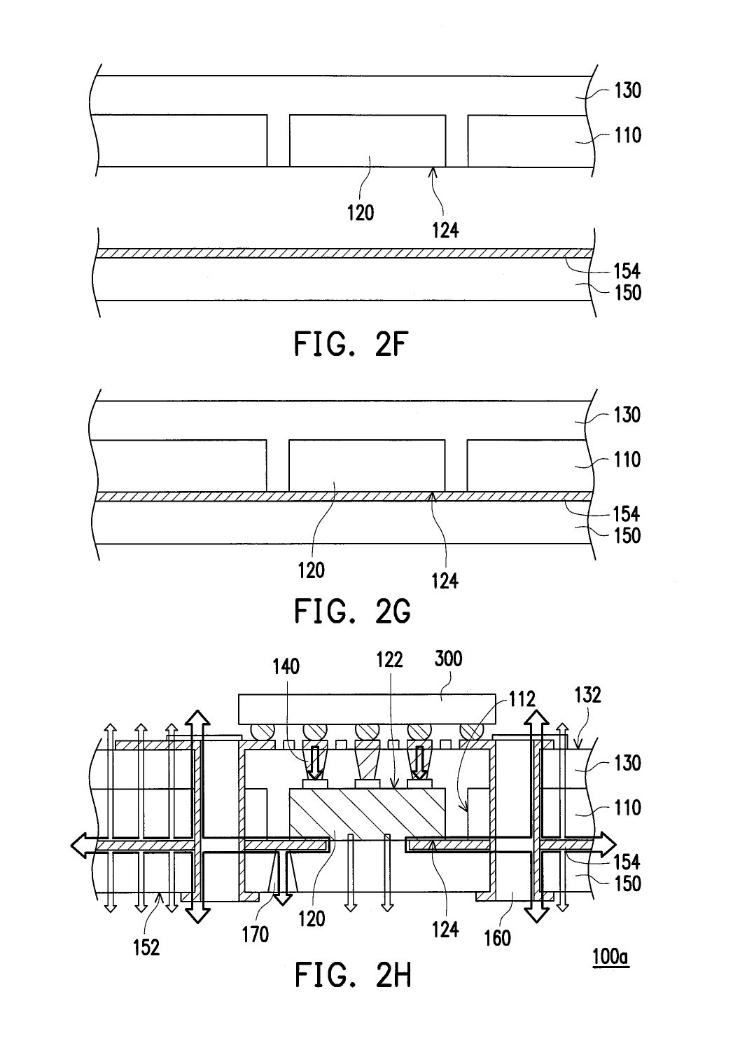

FIGS. 2A to 2H are schematic cross-sectional views illustrating a fabricating process of a wiring board structure according to an embodiment of the invention. In the present embodiment, a fabricating method of the wiring board structure 100 may include the following steps. Firstly, as shown in FIG. 2A, a core layer 110 is provided, and the core layer 110 has a cavity 112 penetrating the core layer 110. Next, as shown in FIG. 2B, the core layer 110 is disposed on a substrate 105.

Next, referring to FIG. 2C, an active cooler 120 is disposed on the substrate 105 and located in the cavity 112. In the present embodiment, the substrate 105 may be formed of, for example, a releasing film, or a specific adhesive partially coated or completely coated on a releasing film. The substrate 105 has characteristic of temporary adhesive which can be easily peeled off and suitable for temporarily carrying and fixing the active cooler 120. Later, the substrate 105 can easily be separated from the active cooler 120 without damaging the active cooler 120. Thereafter, as shown in FIG. 2D, the first dielectric layer 130 covers on the core layer 110 and fills the gap between the cavity 112 and the active cooler 120. As shown in FIG. 2E, the substrate 105 is removed so as to expose a hot surface 124 of the active cooler 120. Next, the first conductive via 140 is formed in the first dielectric layer 130 depicted in FIG. 1 to connect the first outer surface 132 of the first dielectric layer 130 and the cold surface 122 of the active cooler 120, so as to complete the fabrication of the wiring board structure 100. As an application of the wiring board structure 100, the heat-generating component 300 can be disposed on the first outer surface 132 of the first dielectric layer 130 and connected with the first conductive vias 140 as depicted in FIG. 1.

The wiring board structure 100 may be a circuit board or a packaging carrier, in which the cold surface 122 of the active cooler 120 is applied for connecting to the heat-generating component 300 through the first conductive vias 140 for absorbing heat of the heat-generating component 300, and the hot surface 124 is exposed outside of the first dielectric layer 130, so that heat of the hot surface 124 can be directly radiated. Of course, based on layout designs of the components and circuit in the wiring board structure, it is also possible that the hot surface 124 of the active cooler 120 is not exposed to the outside but completely embedded in the wiring board structure 100, which radiates heat by other methods. The method of fabricating a wiring board structure 100a without exposing the hot surface 124 can be done by proceeding to process of FIG. 2F and its subsequent processes after the process of FIG. 2E is completed.

Referring back to FIG. 2F and FIG. 2G, after the substrate 105 is removed, a second dielectric layer 150 is laminated onto the core layer and the hot surface 124 is exposed. A circuit layer 154 is formed on a surface of the second dielectric layer 150 contacting the hot surface 124. The circuit layer 154 is thermally connected with the hot surface 124 and extending to an outer edge of the second dielectric layer 150, so as to laterally radiate the heat from the hot surface 124 through the circuit layer 154. Next, as shown in FIG. 2H, the first conductive via 140 is formed in the first dielectric layer 130 to connect the cold surface 122 and the first outer surface 132. So far, an initial process of fabricating the wiring board structure 100a is completed.

Next, as shown in FIG. 2H, at least one through hole 160 can be selectively formed to penetrate the first dielectric layer 130, the second dielectric layer 150 and the core layer 110, and through hole 160 is connected to the circuit layer 154, so that heat partially conducted from the circuit layer 154 can be radiated through the conductive through hole 160. In addition, at least one second conductive via 170 can also be selectively formed in the second dielectric layer 150 to connect the circuit layer 154 and a second outer surface 152 of the second dielectric layer 150, so as to radiate heat partially conducted from the circuit layer 154 through the second via 170. In other embodiments of the invention, the second conductive via 170 can also directly connect the hot surface 124 and the second outer surface 152 of the second dielectric layer 150, so as to directly radiate the heat from the hot surface 124. A thermal conduction path of the wiring board structure 100a can refer to the hollow arrows depicted in FIG. 2H. As an embodiment of the wiring board structure 100a, the heat-generating component 300 can be disposed on the first outer surface 132 of the first dielectric layer 130, so that the first conductive via 140 connects the heat-generating component 300 and the active cooler 120.

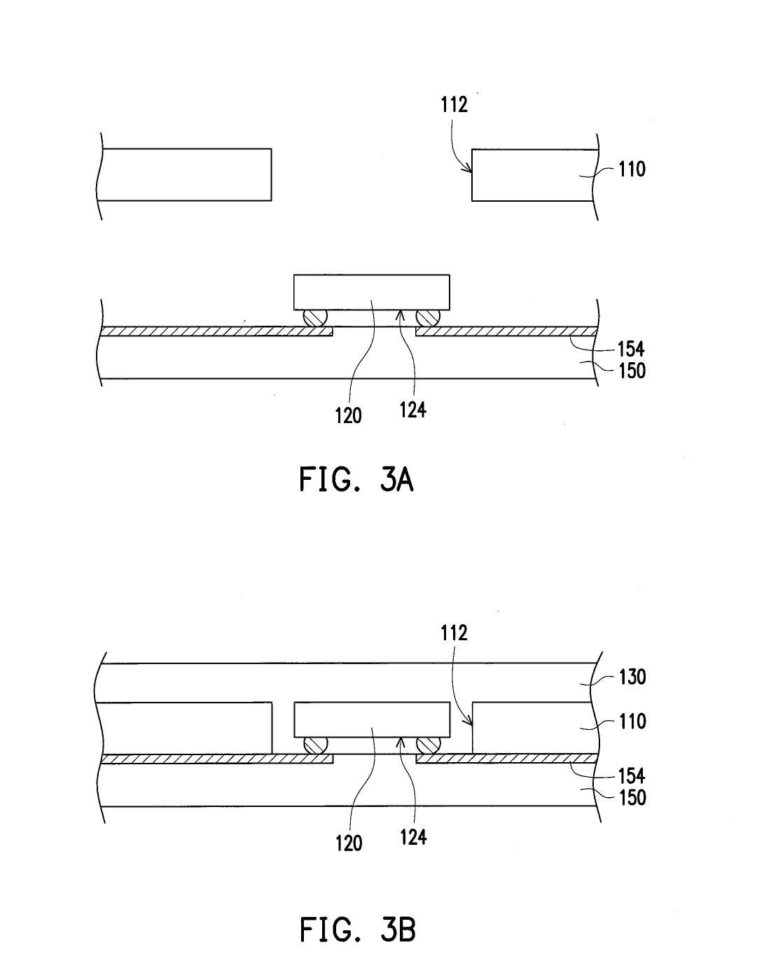

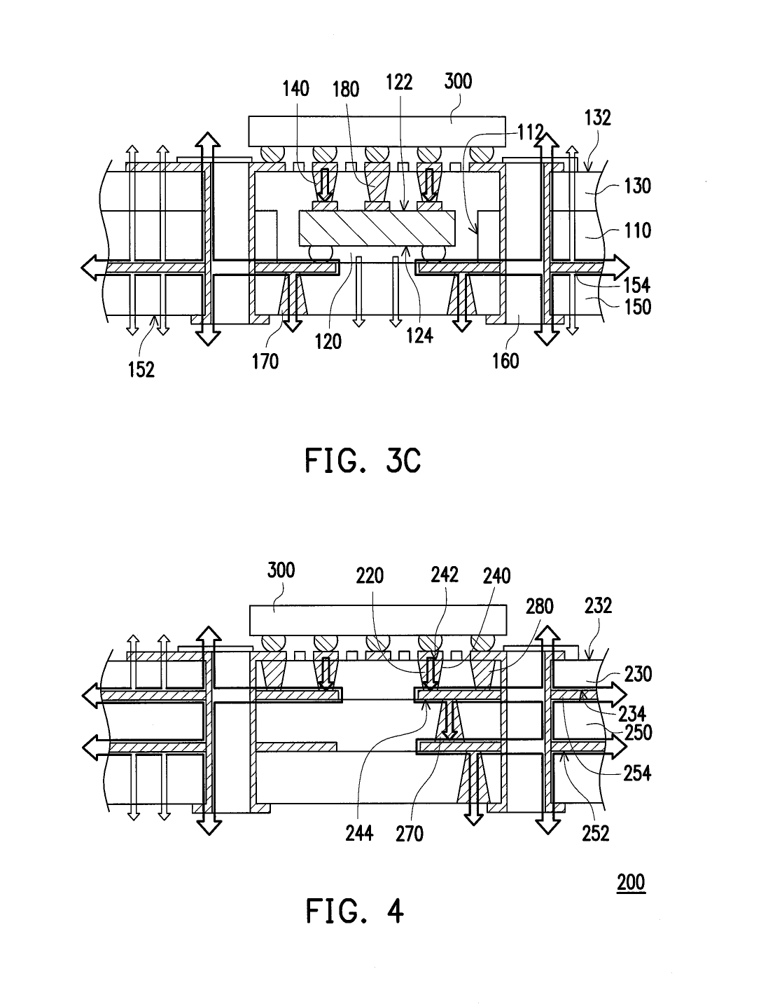

FIGS. 3A to 3C are schematic cross-sectional views illustrating a fabricating process of a wiring board structure according to another embodiment of the invention. In another embodiment of the invention, other fabricating methods may also be adopted to fabricate a wiring board structure 100b. Firstly, as shown in FIG. 3A, a core layer 110 is provided, and an active cooler 120 is disposed on a second dielectric layer 150. The core layer 110 has a cavity 112 penetrating the core layer 110. A surface of the second dielectric layer 150 contacting the active cooler 120 has a circuit layer 154 connected to a hot surface 124 of the active cooler 120 and laterally extending to an outer edge of the second dielectric layer 150, so as to laterally radiate the heat from the hot surface 124 through the circuit layer 154. In the present embodiment, the hot surface 124 of the active cooler 120 can be thermally connected to the circuit layer 154 through, for example, a plurality of solders.

Next, as shown in FIG. 3B, the core layer 110 is disposed on the second dielectric layer 150, and the first dielectric layer 130 covers the core layer 110 and fills the gap between the cavity 112 and the active cooler 120. Next, as shown in FIG. 3C, the first conductive via 140 is formed in the first dielectric layer 130 to connect the cold surface 122 of the active cooler 120 and the first outer surface 132 of the first dielectric layer 130. Next, the heat-generating component 300 is disposed on the first outer surface 132 of the first dielectric layer 130, so that the first conductive via 140 connect the heat-generating component 300 and the active cooler 120. So far, the process of fabricating the wiring board structure 100b may be completed.

Then, as shown in FIG. 3C, at least one through hole 160 can be selectively formed to penetrate the first dielectric layer 130, the second dielectric layer 150 and the core layer 110, and the through hole 160 is connected to the circuit layer 154, so that heat partially conducted from the circuit layer 154 can be radiated through the conductive through hole 160. In addition, at least one second conductive via 170 can also be selectively formed in the second dielectric layer 150 to connect the circuit layer 154 and a second outer surface 152 of the second dielectric layer 150, so as to radiate heat partially conducted from the circuit layer 154 through the second conductive via 170. Of course, in other embodiments of the invention, the second conductive via 170 can also directly connect the hot surface 124 and the second outer surface 152 of the second dielectric layer 150, so as to directly radiate heat of the hot surface 124. A thermal conduction path of the wiring board structure 100a can refer to the hollow arrows depicted in FIG. 3C.

Accordingly, in the wiring board structures 100a and 100b, the cold surface 122 of the active cooler 120 is connected to the heat-generating component 300 through the first conductive via 140, and the hot surface 124 is connected to the circuit layer 154, and the circuit layer 154 laterally extends to the outer edge of the second dielectric layer 150 for absorbing the heat from the heat-generating component 300 through the cold surface 122, and the heat from the hot surface 124 can be radiated through the circuit layer 154. As a result, the heat generated by the heat-generating component 300 during operation can be rapidly dissipated to avoid unnecessary heat accumulation and improve heat dissipation efficiencies of the wiring board structures 100a and 100b.

FIG. 4 is a schematic view of a wiring board structure 200 according to yet another embodiment of the invention. In the present embodiment, a wiring board structure 200 includes an active cooling material 220, a first dielectric layer 230 and a plurality of first conductive vias 240. The first dielectric layer 230 includes a first surface 232 and a second surface 234 opposite to the first surface 232. The first conductive vias 240 are disposed in the first dielectric layer 230 and respectively connecting through the first surface 232 and the second surface 234. The active cooling material 220 is applied to fill each of the first conductive vias 240, so that each of the first conductive vias 240 has a hot surface 242 and a cold surface 244. In the present embodiment, the wiring board structure 200 may further include a second dielectric layer 250 disposed on the second surface 234, and include a circuit layer 254 located on a surface of the second dielectric layer 250 contacting the second surface 234, and extending to an outer edge of the second dielectric layer 250. The circuit layer 254 is connected to the hot surface 244 to laterally radiate the heat through the hot surface 244. As an embodiment of the wiring board structure 200, the heat-generating component 300 can be disposed on the first surface 232 and connected with the cold surface 242 for absorbing the heat of the heat-generating component 300 through the cold surface 242 of the first conductive vias 240.

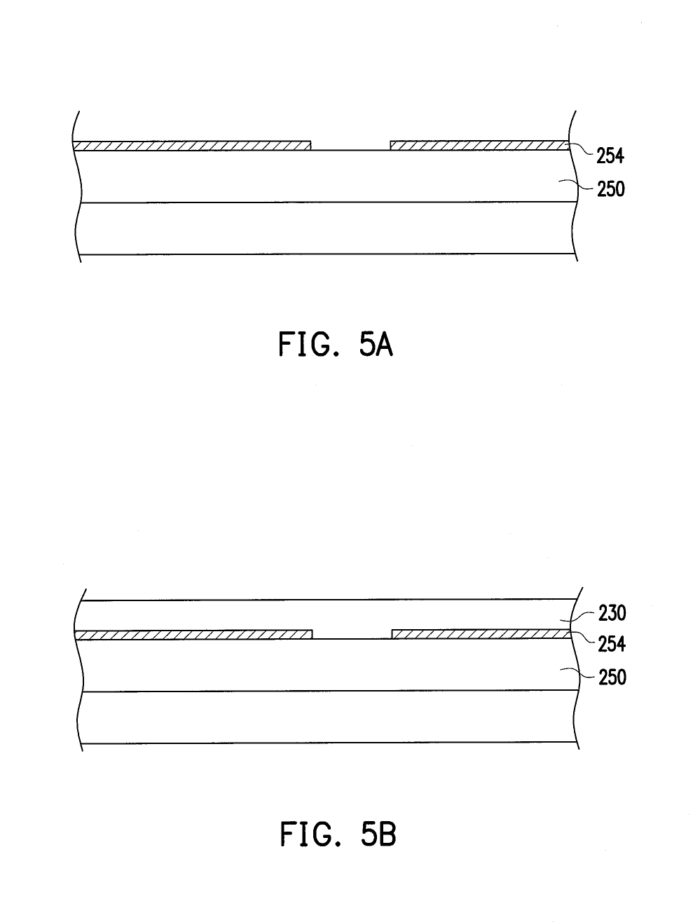

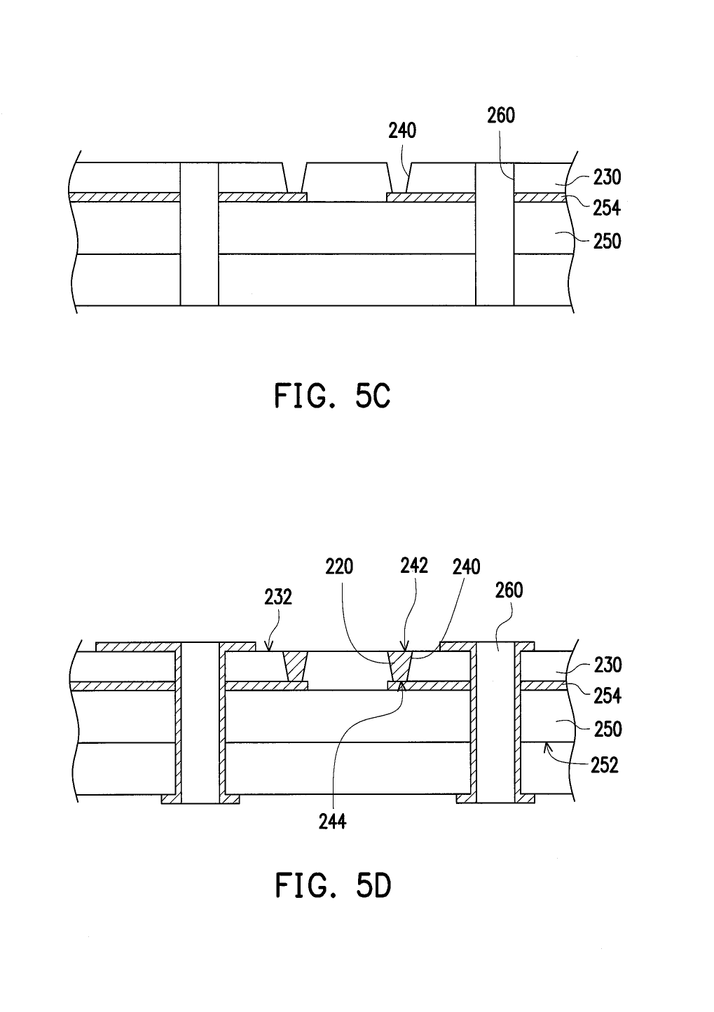

FIGS. 5A to 5D are schematic cross-sectional views of a fabricating process of the wiring board structure depicted in FIG. 4. In the present embodiment, a fabricating method of the wiring board structure 200 may include the following steps. First, a second dielectric layer 250 is provided, and a circuit layer 254 is disposed on a surface of the second dielectric layer 250. The circuit layer 254 extends to an outer edge of the second dielectric layer 250. Next, as shown in FIG. 5B, a first dielectric layer 230 is formed on the second dielectric layer 250. The first dielectric layer 230 has a first surface 232 and a second surface 234 opposite to each other. The second electrode layer 254 is located between the first dielectric layer 230 and the second dielectric layer 250.

Next, as shown in FIG. 5C, a first conductive via 240 is formed at the first dielectric layer 230, and the first conductive via 240 connects through the first surface 232 and the second surface 234. In the present embodiment, as shown in FIG. 5C, at least one conductive through hole 260 is selectively formed, which penetrates the first dielectric layer 230 and the second dielectric layer 250 and connects with the circuit layer 254. The first conductive via 240 and the through hole 260 may be formed by using, for example, laser drilling or mechanical drilling. Of course, the invention is not limited thereto.

Next, as shown in FIG. 5D, the active cooling material 220 is applied to fill the first conductive via 240, so that the first conductive vias 240 can provide active heat conduction after an electric current is conducted, so as to generate a hot surface 242 and a cold surface 244 on two opposite ends of the first conductive vias 240. The hot surface 244 is connected to the circuit layer 254 to laterally conduct the heat from the hot surface 244 to the outer edge of the dielectric layer 230, 250. In the present embodiment, the active cooling material 220 may be a thermal-electric cooler (TEC) which includes a N-type semiconductor material and a P-type semiconductor material, and said materials may be tellurium (Te) and bismuth (Bi) or any other suitable material. In addition, the through hole 260 may also contact the circuit layer 254, so that heat of the circuit layer 254 can be partially radiated through the through hole 260. Thereby, an initial process of fabricating the wiring board structure 200 is completed.

Besides, as shown in FIG. 4, at least one second conductive via 270 may be selectively disposed in the second dielectric layer 250 to connect the circuit 254 and a second outer surface 252 of the second dielectric layer 250, so as to conduct the heat partially conducted from the circuit 254 to the outer layer of the dielectric layer through the second conductive vias 270. Next, with a similar approach, the heat is radiated through the conductive vias in each of the dielectric layers. Of course, in other embodiments of the invention, the second conductive via 270 may also directly connect the hot surface 244 and the second outer surface 252 of the second dielectric layer 250 to directly conduct the heat from the hot surface 244 to the outer layer of the dielectric layers, and radiate the heat through the conductive vias in each of the dielectric layers. A thermal conduction path of the wiring board structure 200 can refer to the hollow arrows depicted in FIG. 4.

In addition, the wiring board structure 200 may further include a plurality of third conductive vias 280 disposed in the first dielectric layer 230. The third conductive vias 280 may be filled in with ordinary conductive material (e.g., copper) configured to facilitate the first conductive via 240 to serve as an electrical conduction between the heat-generating component 300 and the wiring board structure 200.

In summary, in the invention, the active cooler is embedded in the wiring board structure, or the active cooling material is applied to fill the conductive vias of the wiring board structure. Accordingly, with a characteristic in which a cold surface and a hot surface are formed on two opposite ends of the active cooler or the conductive via filled with the active cooling material when an electric current is conducted thereto for providing an active heat conduction, the cold surface can be connected to the heat-generating component through the first conductive vias to absorb the heat generated by the heat-generating component through the cold surface, and radiate the heat through the hot surface. As a result, the wiring board structure of the invention can rapidly dissipate the heat generated by the heat-generating component during operation to avoid unnecessary heat accumulation so as to improve a heat dissipation efficiency of the wiring board structure.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A wiring board structure, adapted to carry a heat-generating component, the wiring board structure comprising:
a core layer having a cavity penetrating through the core layer;
an active cooler including a cold surface and a hot surface, and the active cooler being disposed in the cavity;
a first dielectric layer covering a surface of the core layer and the cold surface, and filling a gap between the cavity and the active cooler, wherein the first dielectric layer has a first outer surface not contacting the core layer and the active cooler for disposing the heat-generating component; and
a plurality of first conductive vias disposed in the first dielectric layer and connecting the cold surface and the first outer surface to connect the heat-generating component and the active cooler.

2. The wiring board structure of claim 1, wherein the first dielectric layer exposes the hot surface.

3. The wiring board structure of claim 1, further comprising a second dielectric layer, wherein the active cooler is disposed on the second dielectric layer by the hot surface, and located in the cavity.

4. The wiring board structure of claim 3, further comprising a circuit layer disposed on the second dielectric layer and extending to an outer edge of the second dielectric layer, and the circuit layer being thermally connected to the hot surface.

5. The wiring board structure of claim 3, further comprising a circuit layer and at least one conductive through hole, the circuit layer disposed on the second dielectric layer and connected to the hot surface, the conductive through hole penetrating through the first dielectric layer, the second dielectric layer and the core layer, and the conductive through hole connecting with the circuit layer.

6. A wiring board structure, adapted to carry a heat-generating component, the wiring board structure comprising:
a first dielectric layer including a first surface and a second surface opposite to the first surface;
a plurality of first conductive vias disposed in the first dielectric layer and respectively connecting through the first surface and the second surface; and
an active cooling material filling each of the first conductive vias so that each of the first conductive vias has a hot surface and a cold surface respectively corresponding to the second surface and the first surface of the first dielectric layer, wherein the first surface and the cold surface are respectively for disposing and connecting with the heat-generating component.

7. The wiring board structure of claim 6, further comprising a second dielectric layer disposed on the second surface, and a circuit layer located on a surface of the second dielectric layer contacting the second surface and extending to an outer edge of the second dielectric layer, and the circuit layer connecting with the hot surfaces.

8. The wiring board structure of claim 6, further comprising a second dielectric layer and a plurality of second conductive vias, the second dielectric layer disposed on the second surface, and the second conductive vias disposed in the second dielectric layer and respectively connecting the hot surfaces and a second outer surface of the second dielectric layer.

9. The wiring board structure of claim 7, further comprising a plurality of second conductive vias disposed in the second dielectric layer and respectively connecting the circuit layer and a second outer surface of the second dielectric layer.

10. The wiring board structure of claim 7, further comprising at least one conductive through hole penetrating the first dielectric layer and the second dielectric layer, and connecting with the circuit layer.
